(19) United States
(12) Patent Application Publication
(10) Pub. No.: US 2013/0258231 A1
(43) Pub. Date: Oct. 3, 2013

(54) LIQUID CRYSTAL DISPLAY MODULE AND FRAME STRUCTURE THEREOF

(71) Applicants: Quan Li, Shenzhen (CN); Yajun Yu, Shenzhen (CN)

(72) Inventors: Quan Li, Shenzhen (CN); Yajun Yu, Shenzhen (CN)

(73) Assignee: Shenzhen China Star Optoelectronics Technology Co., Ltd., Guangdong (CN)

(21) Appl. No.: 13/510,614

(22) PCT Filed: Apr. 12, 2012
(86) PCT No.: PCT/CN12/73879

§ 371 Date: May 17, 2012

(30) Foreign Application Priority Data
Mar. 28, 2012 (CN) 201210086430.0

(51) Int. Cl. H05K 7/18; F21V 8/00; G02F 1/13357

(52) U.S. Cl. 349/58; 362/612; 312/223.1

(57) ABSTRACT

The present invention provides a frame structure of a liquid crystal display module, comprises a front frame having a slot defined in a displaying surface thereof. A backframe is partially disposed within the front fame. The backframe is provided with an embossed portion engaged into the slot. The present invention further provides a liquid crystal display module. The present invention can effectively prevent the external and excessive force from creating a deformation of the front frame when external and excessive force is applied to drive a screw to interlock the front frame and the backframe. Accordingly, the unwanted deformation which may jeopardize the aesthetic appearance and leakage of light source can be completely avoided.

### FIELD OF THE INVENTION

The present invention relates to display device, and more particularly to a liquid crystal display module and its frame structure.

### BACKGROUND OF THE INVENTION

Referring to FIG. 1, a cross sectional view of an existing liquid crystal display module. As disclosed thereof, the liquid crystal display module includes a front frame 101, a backframe 102, a light source 103, a waveguide 104, an intermediate frame 105, a liquid crystal display panel 106, an optic film 107 and a shimmer 108.

Referring to FIG. 2, it is still a cross sectional view of liquid crystal display module in which a screw is installed. As disclosed thereof, when the locking torque applied to the screw 109 is excessive, both the frontal frame 101 and the backframe 102 will be influenced by the side force. Accordingly, an end of the front frame 101 will be depressed by the shimmer 108, as marked by arrow 2. In this case, a leakage of light will be encountered. An aesthetic appearance of the liquid crystal display module will also be affected.

### SUMMARY OF THE INVENTION

The present invention is to provide a technology of a frame structure of a liquid crystal display module and a liquid crystal display module. The present invention can effectively prevent the external and excessive force from creating a deformation of the front frame when external and excessive force is applied to drive a screw to interlock the front frame and the backframe. Accordingly, the unwanted deformation which may jeopardize the aesthetic appearance and leakage of light source can be completely avoided.

In order to resolve the existing issue, a frame structure of a liquid crystal display module is provided, and it comprises a front frame having slot at a displaying surface thereof. A backframe is partially disposed within the front frame, and configured with side walls, bent portion, and an embossed portion,. An upper end of the sidewalls extends toward the displaying surface of the front frame, and connected to a first end of the bent portion. A second end of the bent portion is connected to the embossed portion. Wherein both the embossed portion and the sidewalls are perpendicular to the bent portion and the embossed portion is disposed within the slot and elastically abuts against at least an inner wall of the slot.

Wherein the frame structure further comprises a waveguide disposed on a bottom surface of the backframe, the bottom surface of the backframe is interlinked to a lower portion of the sidewalls, the side all of the backframe is defined with a compartment of installation of an LED light tube therein such that a center of the LED light tube is coplanar with a center of the waveguide.

Wherein the compartment is dimensioned to receive the LED light tube therein.

Wherein the LED light tube is securely disposed within the compartment by means of soldering, mechanical engagement, gluing or screwing.

Wherein the slot defined in the front frame is dimensioned to snugly receive the embossed portion therein.

The present invention provides a second embodiment so as to address the existing issue. A frame structure of a liquid crystal display module is provided and it comprises a front frame defined with a slot on a displaying surface. And a backframe is partially disposed within the front frame, and includes an embossed portion received within the slot of the front frame.

Wherein the backframe further comprises a bent portion, and an embossed portion. An upper end of the sidewalls extends toward the displaying surface of the front frame, and is connected to a first end of the bent portion. A second end of the bent portion is connected to the embossed portion. Wherein both the embossed portion and the sidewalls are perpendicular to the bent portion.

Wherein the frame structure further comprises a waveguide disposed on a bottom surface of the backframe, the bottom surface of the backframe is interlinked to a lower portion of the sidewalls, the side all of the backframe is defined with a compartment of installation of an LED light tube therein such that a center of the LED light tube is coplanar with a center of the waveguide.

Wherein the compartment is dimensioned to receive the LED light tube therein.

Wherein the LED light tube is securely disposed within the compartment by means of soldering, mechanical engagement, gluing or screwing.

Wherein the slot defined in the front frame is dimensioned to snugly receive the embossed portion therein.

Wherein the embossed portion is disposed within the slot and elastically abuts against at least an inner wall of the slot.

The present invention provides a second embodiment so as to address the existing issue. A liquid crystal display module incorporated with a frame structure is provided, and the frame structure comprises a front frame defined with a slot on a displaying surface. And a backframe is partially disposed within the front frame, and includes an embossed portion received within the slot of the front frame.

Wherein further comprises an optic film disposed on a waveguide disposed on the backframe.

Wherein the liquid crystal display module further comprises a liquid crystal display panel disposed on an intermediate frame, and a shimmer disposed between the liquid crystal display panel and the front frame.

The advantage of the present invention can be readily demonstrated by the provision of a slot defined in the front frame, and an embossed portion on the backframe. The dimensionally engagement between the slot and the embossed portion can properly neutralize a side force by movement of the embossed portion within the slot when a side force is encountered during the assembling of the module by means of screw interlocked the frame structure. Accordingly, aesthetic appearance of the display can be ensured, and the leakage of the light can be avoided.

### BRIEF DESCRIPTION OF DRAWINGS

FIG. 1 is a cross sectional view of a prior art liquid crystal display module;

FIG. 2 is a cross sectional view of a prior art liquid crystal display module illustrating a screw is driven in;

FIG. 3 is a cross sectional view of a first embodiment of a liquid crystal display module made according to the present invention;

FIG. 4 is a cross sectional view of the first embodiment of the liquid crystal display module of the present invention illustrating a screw is driven in; and

FIG. 5 is a cross sectional view of the first embodiment of the liquid crystal display module of the present invention in which a thickness index of a waveguide is marked.

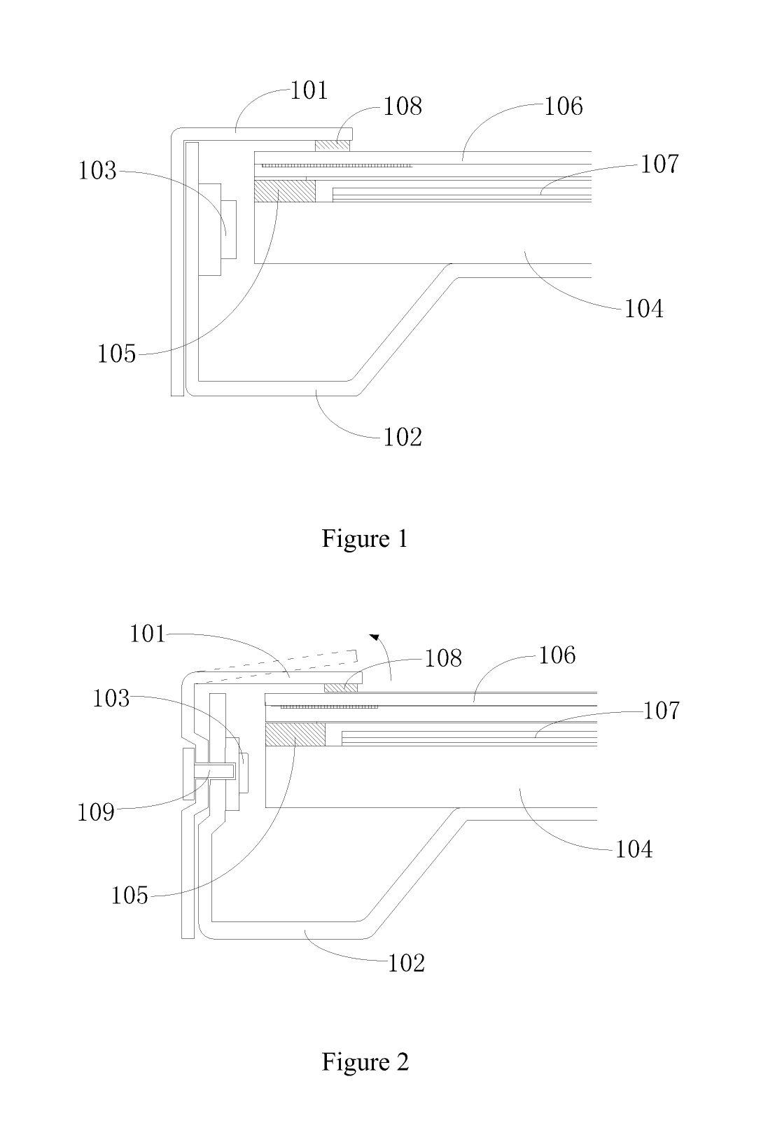

### DETAILED DESCRIPTION FOR PREFERRED EMBODIMENT

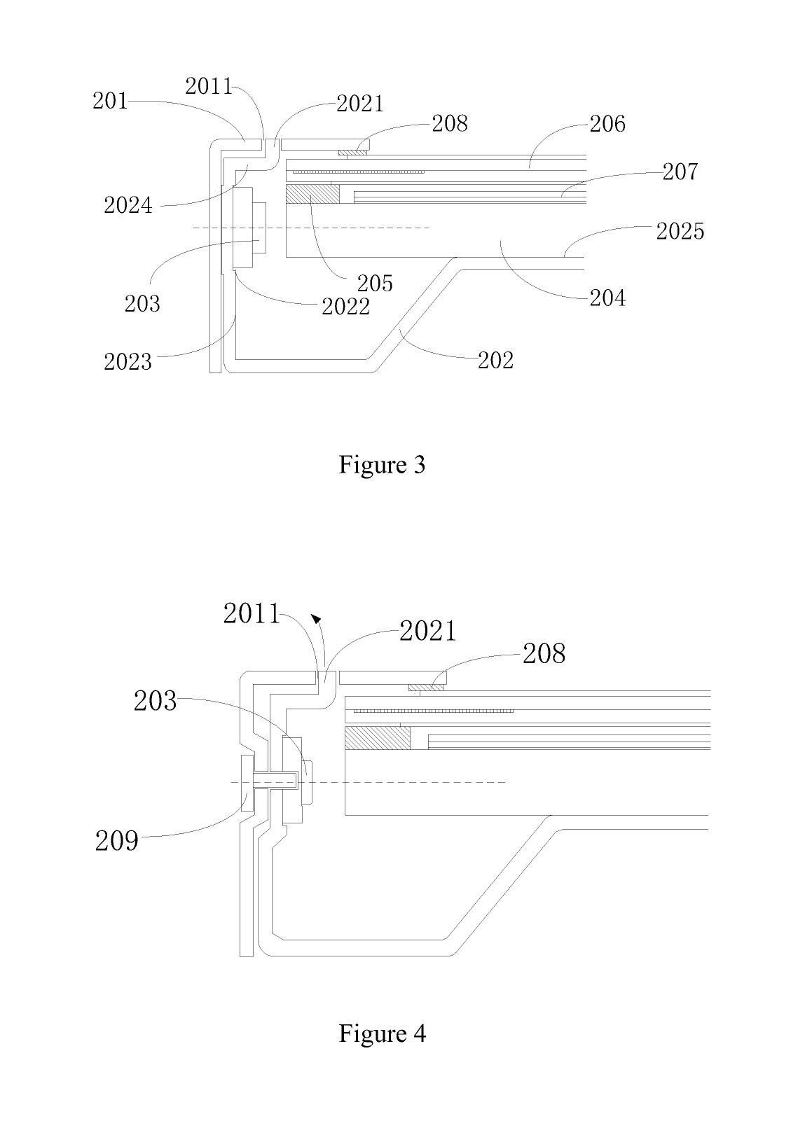

Firstly, please refer to FIG. 3, a cross sectional view of a liquid crystal display module made in accordance with a first embodiment of the present invention is disclosed. As shown, the liquid crystal display module 206 generally includes a frame structure which includes a front frame 201 and a backframe 202. The front frame 201 includes a first extension (not labeled) on a displaying surface, and a sidewall (not labeled) extending from an end of the extension toward the backframe 202. The backframe 202 includes a bottom (not labeled) surface corresponding to the first extension, and a sidewall 2023 corresponding to the sidewall of the front frame 201. Wherein, the sidewall 2023 of the backframe 202 is disposed within the sidewall of the front frame 202 and the first extension. The first extension is defined with a slot 2011, and the sidewall 2023 of the backframe 202 is provided with embossed portion 2021 which is dimensioned to be received into the slot 2011. In a preferred embodiment, the slot 2011 can be embodied into a polygonal shape, circular shape, or an oval shape. As mentioned, both the slot 2011 and the embossed portion 2021 are dimensioned such that a robust fit and engagement are ensured. In addition, in an alternative embodiment, the dimension of the slot 2011 can be slightly larger than the dimension of the embossed portion 2021 such that the embossed portion 2021 can elastically abut against at least an inner wall of the slot 2011. On the other hand, the slot can be embodied as an opening, or a recess or half hole.

The backframe 202 includes the sidewall 2023 and a curve portion 2024. A top of the sidewall 2023 of the backframe 202 extends toward the displaying surface of the front frame 201 and eventually terminated with an end of the curve portion 2024. The other end of the curve portion 2024 is interconnected to the embossed portion 2021. Both the embossed portion 2021 and the sidewall 2023 of the backframe 202 are perpendicular to the curve portion 2024. A top of the embossed portion 2021 projects beyond the displaying surface of the front frame 201 and reaches into the slot 2011.

The frame structure further includes a waveguide 204 which is disposed on a bottom surface 2025 of the backframe 202. The bottom surface 2025 is interconnected to a lower end of the sidewall 2023 of the backframe 202. The sidewall 2023 is further defined with a compartment 2022 in which an LED light tube 203 is disposed. The dimension is specially arranged that such that a center of the LED light tube 203 is coplanar to a center of the waveguide 204. The compartment 204 is also dimensioned and specially shaped so as to properly receive the LED light tube 203 therein.

The LED light tube 203 is securely disposed within the compartment by means of soldering, mechanical engagement, gluing or a screw 209.

Still referring to FIG. 3, the liquid crystal display module further includes an optic film 207, a liquid crystal display panel 206, an intermediate frame 205, and a shimmer 208. The optic film 207 is disposed on the waveguide 204. The liquid crystal display panel 206 is disposed onto the intermediate frame 205. The shimmer 208 is disposed between the front frame 201 and the liquid crystal display panel 206.

Referring to FIG. 4 which is a cross sectional view of a first embodiment of the liquid crystal display module showing a screw 209 is driven in from a side thereof. As shown in FIG. 4, when an external and excessive force is applied to drive the screw 209 to interlock the front frame 201 and the backframe 202 in which the LED light tube 203 is installed, the embossed portion 2021 of the backframe 202 will be moved within the slot 2011, as marked by Arrow in FIG. 4. By this arrangement, the movement of the embossed portion 2021 within the slot 2011 will neutralize the transversal force so as to prevent the external and excessive force from creating a deformation of the front frame 201 by the shimmer 208. Accordingly, the unwanted deformation which may jeopardize the aesthetic appearance and leakage of light source can be completely avoided.

It should be noted that in FIG. 4, the slot is defined in an area in which an light inlet side (i.e. in which the LED light tube 203 is disposed) of the liquid crystal display module is designed and defined in the front frame, while the embossed portion is arranged on the backframe. However, in other alternative, the slot can be designed and arranged on a non-inlet side, i.e. a side opposite to the compartment in which the LED light tube 203 is disposed, while the embossed portion is disposed on the backframe. Both can reach an intended purpose of preventing the front frame 201 from deforming

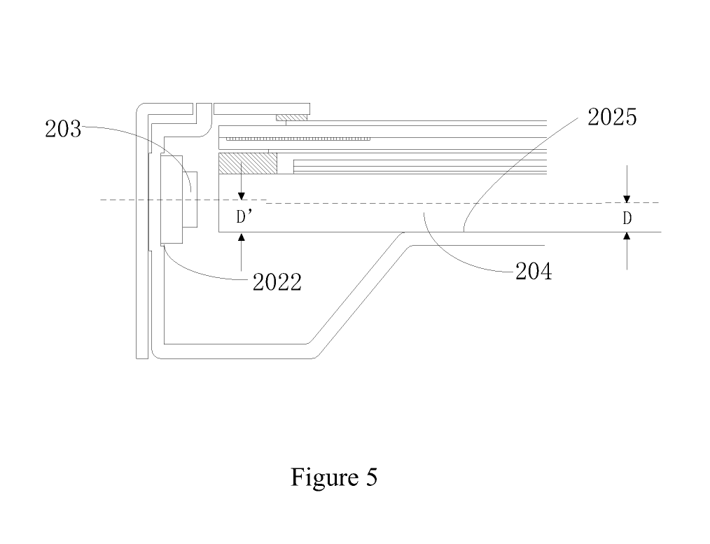

Referring to FIG. 5, it is a cross sectional view of the first embodiment of the liquid crystal display module of the present invention in which a thickness index of a waveguide is marked. As shown in FIG. 5, the backframe 202 is defined with a compartment 2022 in which the LED light tube 203 is precisely installed. Accordingly, in assembling, as long as a distance D′ measured from a center of the compartment 2022 to the bottom surface 2025 of the waveguide 204 is equal to a distance D between the central axis of the waveguide 204 to the bottom surface 2025 of the waveguide 204. Then, after the LED light tube 203 is disposed in the compartment 2022, the center of the LED light tube 203 is coplanar to the central axis of the waveguide 204. As a result, the illuminating efficiency of the LED light tube 203 can be guaranteed. In the actual implementation, controlling the distance D from the central axis of the waveguide 204 to the bottom surface 2025 of the waveguide 204 can be readily reached without any difficulty. Accordingly, by providing the compartment 2022 in the sidewall 2023 of the backframe 202 to control the true position of the LED light tube 203, the center of the LED light tube 203 is coplanar to the center of the waveguide 204.

By the technology provided and described above, i.e. defining a slot 2011 on the front frame 201, and an embossed portion 2021 on the backframe 202 which is received in the slot, when an external and excessive force is applied to drive the screw 209 to interlock the front frame 201 and the backframe 202, the transversal force applied thereto will drive the embossed portion 2021 to move within the slot 2011 so as to neutralize the transversal force. As a result, the unwanted deformation which may jeopardize the aesthetic appearance and leakage of light source can be completely avoided.

In addition, the sidewall 2023 of the backframe 202 is defined with a compartment 2022 in which an LED light tube 203 is installed. The dimension is specially arranged that such that a center of the LED light tube 203 is coplanar to a center of the waveguide 204. The compartment 204 is also dimensioned and specially shaped so as to properly receive the LED light tube 203 therein.

The above described is merely preferred embodiment of the present invention, and it is merely for illustration while not for limitation. As a result, any alternation and modification or any equivalents based on the specification as well as the drawings will be covered by the attached claims even they are applied to other fields of technology directly or indirectly.

1. A frame structure of a liquid crystal display module, comprising:
a front frame having slot at a displaying surface thereof; and
a backframe partially disposed within the front frame, and configuring with side walls, bent portion, and an embossed portion, a upper end of the sidewalls extending toward the displaying surface of the front frame, and connected to a first end of the bent portion, a second end of the bent portion being connected to the embossed portion, wherein both the embossed portion and the sidewalls are perpendicular to the bent portion, the embossed portion being disposed within the slot and elastically abutting against at least an inner wall of the slot.

2. The frame structure of a liquid crystal display module as recited in claim 1, wherein the frame structure further comprises a waveguide disposed on a bottom surface of the backframe, the bottom surface of the backframe is interlinked to a lower portion of the sidewalls, the side all of the backframe is defined with a compartment of installation of an LED light tube therein such that a center of the LED light tube is coplanar with a center of the waveguide.

3. The frame structure of a liquid crystal display module as recited in claim 1, wherein the compartment is dimensioned to receive the LED light tube therein.

4. The frame structure of a liquid crystal display module as recited in claim 3, wherein the LED light tube is securely disposed within the compartment by means of soldering, mechanical engagement, gluing or screwing.

5. The frame structure of a liquid crystal display module as recited in claim 1, wherein the slot defined in the front frame is dimensioned to snugly receive the embossed portion therein.

6. A frame structure of a liquid crystal display module, comprising:
a front frame defined with a slot on a displaying surface; and
a backframe partially disposed within the front frame, and including an embossed portion received within the slot of the front frame.

7. A frame structure of a liquid crystal display module as recited in claim 1, wherein the backframe further comprises a bent portion, and an embossed portion, a upper end of the sidewalls extending toward the displaying surface of the front frame, and connected to a first end of the bent portion, a second end of the bent portion being connected to the embossed portion, wherein both the embossed portion and the sidewalls are perpendicular to the bent portion.

8. The frame structure of a liquid crystal display module as recited in claim 7, wherein the frame structure further comprises a waveguide disposed on a bottom surface of the backframe, the bottom surface of the backframe is interlinked to a lower portion of the sidewalls, the side all of the backframe is defined with a compartment of installation of an LED light tube therein such that a center of the LED light tube is coplanar with a center of the waveguide.

9. The frame structure of a liquid crystal display module as recited in claim 8, wherein the compartment is dimensioned to receive the LED light tube therein.

10. The frame structure of a liquid crystal display module as recited in claim 9, wherein the LED light tube is securely disposed within the compartment by means of soldering, mechanical engagement, gluing or screwing.

11. The frame structure of a liquid crystal display module as recited in claim 6, wherein the slot defined in the front frame is dimensioned to snugly receive the embossed portion therein.

12. The frame structure of a liquid crystal display module as recited in claim 6, wherein the embossed portion disposed within the slot and elastically abuts against at least an inner wall of the slot.

13. A liquid crystal display module incorporated with a frame structure, the frame structure comprising:
a front frame defined with a slot on a displaying surface; and
a backframe partially disposed within the front frame, and including an embossed portion received within the slot of the front frame.

14. The liquid crystal display module as recited in claim 13, wherein further comprises an optic film disposed on a waveguide disposed on the backframe.

15. The liquid crystal display module as recited in claim 14, wherein the liquid crystal display module further comprises a liquid crystal display panel disposed on an intermediate frame, and a shimmer disposed between the liquid crystal display panel and the front frame.
